(19) United States
(12) Patent Application Publication
(10) Pub. No.: US 2025/0359439 A1
(43) Pub. Date: Nov. 20, 2025

(54) DISPLAY DEVICE AND MANUFACTURING METHOD THEREOF

(71) Applicant: Japan Display Inc., Tokyo (JP)

(72) Inventors: Daichi HOSOKAWA, Tokyo (JP); Sho YANAGISAWA, Tokyo (JP); Hideyuki TAKAHASHI, Tokyo (JP)

(73) Assignee: Japan Display Inc., Tokyo (JP)

(21) Appl. No.: 19/195,759

(22) Filed: May 1, 2025

(30) Foreign Application Priority Data
May 20, 2024 (JP) 2024-081950

(51) Int. Cl. H10K 59/122; H10K 59/12; H10K 59/80

(52) U.S. Cl. CPC H10K 59/122; H10K 59/1201; H10K 59/873

(57) ABSTRACT

According to one embodiment, a display device includes a substrate, an organic insulating layer over a display area and a surrounding area, a lower electrode, a rib layer having a pixel aperture, an organic layer which covers the lower electrode through the pixel aperture, an upper electrode which covers the organic layer, and a first partition which includes a first lower portion and a first upper portion, and surrounds the pixel aperture. The surrounding area has a first area which is formed along an outer edge of the substrate and in which the organic insulating layer is not provided, and a second area which is formed along the outer edge and overlaps part of the first area and in which the rib layer is not provided.

### CROSS-REFERENCE TO RELATED APPLICATIONS

This application is based upon and claims the benefit of priority from Japanese Patent Application No. 2024-081950, filed May 20, 2024, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. In this type of display devices, a technique for improving the yield is required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is a schematic cross-sectional view of a display panel along the III-III line of FIG. 2.

FIG. 4 is a schematic plan view of a mother substrate according to the first embodiment.

FIG. 5 is a schematic plan view of a panel portion according to the first embodiment.

FIG. 6 is a schematic plan view in which the vicinity of a cut line in FIG. 5 is enlarged.

FIG. 7 is the schematic cross-sectional view of the panel portion PP along the VII-VII line of FIG. 6.

FIG. 8 is a schematic cross-sectional view showing an example of the structure of a portion in which the dam structure and cut line shown in FIG. 5 intersect each other.

FIG. 9 is a schematic cross-sectional view showing another example of the structure of a portion in which the dam structure and cut line shown in FIG. 5 intersect each other.

FIG. 10 is a schematic cross-sectional view showing an example of the structure of a portion in which the line and cut line shown in FIG. 5 intersect each other.

FIG. 11 is a flowchart showing an example of the manufacturing method of the display device according to the first embodiment.

FIG. 12A is a schematic cross-sectional view showing the manufacturing process of the display device.

FIG. 12B is a schematic cross-sectional view showing a process following FIG. 12A.

FIG. 12C is a schematic cross-sectional view showing a process following FIG. 12B.

FIG. 12D is a schematic cross-sectional view showing a process following FIG. 12C.

FIG. 12E is a schematic cross-sectional view showing a process following FIG. 12D.

FIG. 12F is a schematic cross-sectional view showing a process following FIG. 12E.

FIG. 12G is a schematic cross-sectional view showing a process following FIG. 12F.

FIG. 12H is a schematic cross-sectional view showing a process following FIG. 12G.

FIG. 12I is a schematic cross-sectional view showing a process following FIG. 12H.

FIG. 12J is a schematic cross-sectional view showing a process following FIG. 12I.

FIG. 13 is a schematic cross-sectional view showing the vicinity of the outer edge of a substrate in the display device according to the first embodiment.

FIG. 14 is a schematic cross-sectional view of the vicinity of a cut line in a panel portion according to a second embodiment.

FIG. 15 is a schematic cross-sectional view of the vicinity of a cut line in a panel portion according to a third embodiment.

FIG. 16 is a schematic cross-sectional view of the vicinity of a cut line in a panel portion according to a fourth embodiment.

### DETAILED DESCRIPTION

In general, according to one embodiment, a display device comprises a substrate, an organic insulating layer provided above the substrate over a display area which displays an image and a surrounding area located around the display area, a lower electrode provided above the organic insulating layer in the display area, a rib layer provided above the organic insulating layer and the lower electrode and having a pixel aperture which overlaps the lower electrode, an organic layer which covers the lower electrode through the pixel aperture and emits light based on application of voltage, an upper electrode which covers the organic layer, and a first partition which includes a first lower portion provided above the rib layer and a first upper portion having an end portion protruding from a side surface of the first lower portion, and surrounds the pixel aperture. The surrounding area has a first area which is formed along an outer edge of the substrate and in which the organic insulating layer is not provided, a second area which is formed along the outer edge and overlaps part of the first area and in which the rib layer is not provided.

According to another embodiment, a manufacturing method of a display device includes forming an organic insulating layer which has a first groove surrounding a display area above a substrate, forming a lower electrode above the organic insulating layer in the display area, forming a rib layer above the organic insulating layer and the lower electrode, forming, in the display area, a first partition which includes a first lower portion provided above the rib layer and a first upper portion having an end portion protruding from a side surface of the first lower portion, forming a pixel aperture which overlaps the lower electrode in the rib layer, forming an organic layer which covers the lower electrode through the pixel aperture and emits light based on application of voltage, forming an upper electrode which covers the organic layer, forming a second groove which overlaps part of the first groove in the rib layer by etching for the rib layer, and cutting the substrate along a cut line which overlaps the first groove and the second groove.

The configuration and manufacturing method of the display device described above can improve the yield of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

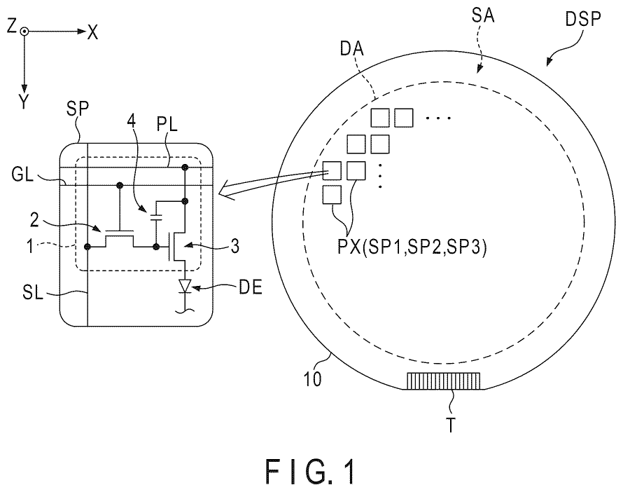

FIG. 1 is a diagram showing a configuration example of a display device DSP according to a first embodiment. The display device DSP comprises an insulating substrate 10. The substrate 10 has a display area DA which displays images, and a surrounding area SA around the display area DA. The substrate 10 may be glass or a resinous film having flexibility.

In the embodiment, the shape of each of the substrate 10 and the display area DA is a circle as seen in plan view. It should be noted that the shape of the substrate 10 or the display area DA in plan view is not limited to a circle and may be another shape such as a rectangle, a square or an oval.

The display area DA comprises a plurality of pixels PX arrayed in matrix in an X-direction and a Y-direction. Each pixel PX includes a plurality of subpixels SP which display different colors. This embodiment assumes a case where each pixel PX includes a blue subpixel SP1, a green subpixel SP2 and a red subpixel SP3. Each pixel PX may include a subpixel SP which exhibits another color such as white in addition to subpixels SP1, SP2 and SP3 or instead of one of subpixels SP1, SP2 and SP3.

The display device DSP further comprises a terminal portion T provided in the surrounding area SA. For example, a flexible printed circuit which applies voltage and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply a scanning signal to the pixel circuit 1 of each subpixel SP, a plurality of signal lines SL which supply a video signal to the pixel circuit 1 of each subpixel SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. One of the source electrode and drain electrode of the pixel switch 2 is connected to the signal line SL. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

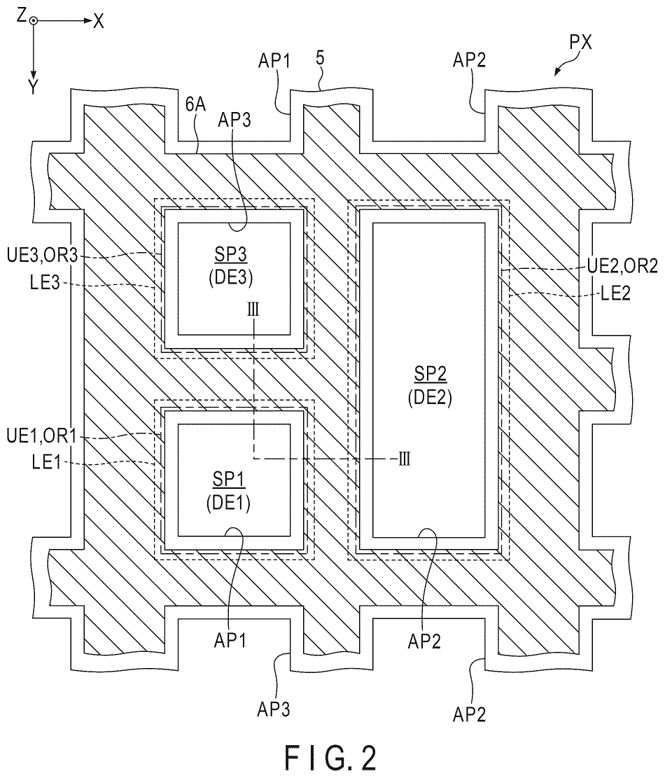

FIG. 2 is a schematic plan view showing an example of the layout of subpixels SP1, SP2 and SP3 constituting a pixel PX. In the example of FIG. 2, subpixels SP1 and SP3 are arranged in the Y-direction. Each of subpixels SP1 and SP3 is adjacent to subpixel SP2 in the X-direction.

When subpixels SP1, SP2 and SP3 are provided in line with this layout, a column in which subpixels SP1 and SP3 are alternately provided in the Y-direction and a column in which a plurality of subpixels SP2 are repeatedly provided in the Y-direction are formed in the display area DA. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures AP1, AP2 and AP3 in subpixels SP1, SP2 and SP3, respectively. In the example of FIG. 2, the pixel apertures AP1 and AP3 are rectangles whose areas are equal to each other. The pixel aperture AP2 is a rectangle which is elongated in the Y-direction relative to the pixel apertures AP1 and AP3. It should be noted that the shape of the pixel aperture AP1, AP2 or AP3 is not limited to this example.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib layer 5 surrounds each of these display elements DE1, DE2 and DE3.

A conductive partition (first partition) 6A is provided above the rib layer 5. The partition 6A functions as lines which apply common voltage to the upper electrodes UE1, UE2 and UE3. The partition 6A overlaps the rib layer 5 as a whole and has a planar shape similar to that of the rib layer 5. The partition 6A surrounds each of the pixel apertures AP1, AP2 and AP3.

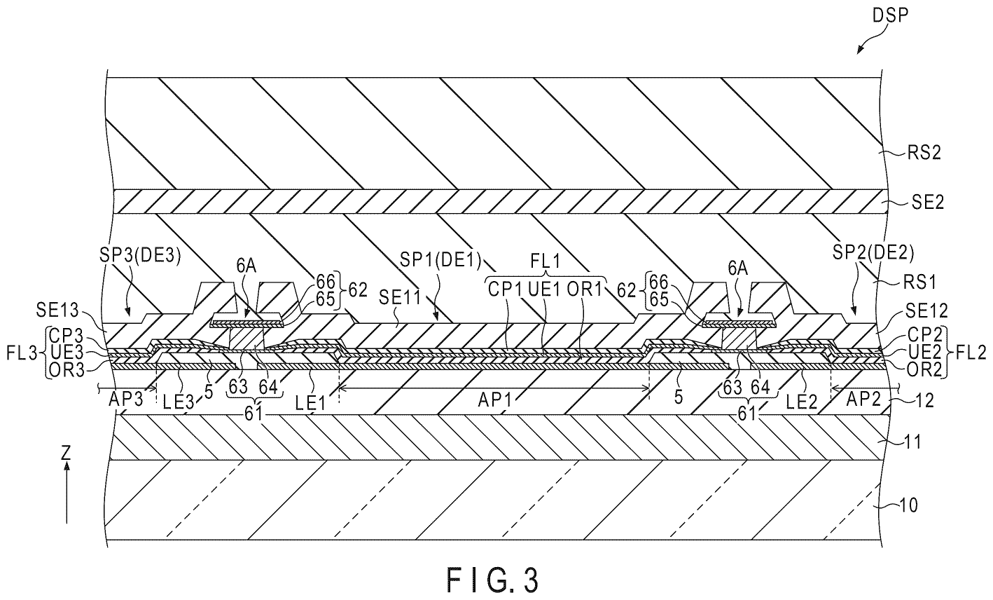

FIG. 3 is the schematic cross-sectional view of the display device DSP along the III-III line of FIG. 2. A circuit layer 11 is provided on the substrate 10 described above. The circuit layer 11 includes various circuits and lines such as the pixel circuits 1, scanning lines GL, signal lines SL and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6A includes a conductive lower portion (first lower portion) 61 provided on the rib layer 5 and an upper portion (first upper portion) 62 provided on the lower portion 61. The upper portion 62 has a width greater than that of the lower portion 61. In other words, the partition 6A has an overhang shape in which the both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

In the example of FIG. 3, the upper portion 62 comprises a first top layer 65, and a second top layer 66 provided on the first top layer 65. For example, the width of the second top layer 66 is slightly less than that of the first top layer 65. It should be noted that the configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the lower portions 61 of the partition 6A.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

Sealing layers (first to third sealing layers) SE11, SE12 and SE13 are provided in subpixels SP1, SP2 and SP3, respectively. The sealing layer SE11 continuously covers the display element DE1 and the partition 6A around the display element DE1. The sealing layer SE12 continuously covers the display element DE2 and the partition 6A around the display element DE2. The sealing layer SE13 continuously covers the display element DE3 and the partition 6A around the display element DE3.

In the example of FIG. 3, the sealing layer SE11 located on the partition 6A between subpixels SP1 and SP2 is spaced apart from the sealing layer SE12 located on this partition 6A. The sealing layer SE11 located on the partition 6A between subpixels SP1 and SP3 is spaced apart from the sealing layer SE13 located on this partition 6A. It should be noted that two of the sealing layers SE11, SE12 and SE13 may be in contact with each other above the partition 6A.

For example, a gap is formed between each of the sealing layers SE11, SE12 and SE13 and the upper portion 62 of the partition 6A. The stacked films FL1, FL2 and FL3 may be provided in at least part of these gaps.

The sealing layers SE11, SE12 and SE13 are covered with a resin layer (first resin layer) RS1. The resin layer RS1 is covered with a sealing layer SE2. The sealing layer SE2 is covered with a resin layer (second resin layer) RS2. The resin layers RS1 and RS2 and the sealing layer SE2 are continuously provided in at least the entire display area DA and partly extend in the surrounding area SA as well.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA).

The electrodes which constitute the touch panel described above may be provided on the sealing layer SE2. Color filters corresponding to the colors of subpixels SP1, SP2 and SP3 may be provided above the display elements DE1, DE2 and DE3, respectively.

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6A is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

The first top layer 65 of the partition 6A is formed of, for example, a metal material. The second top layer 66 of the partition 6A is formed of, for example, a conductive oxide. For the metal material forming the first top layer 65, for example, titanium, titanium nitride, molybdenum, tungsten, a molybdenum-tungsten alloy or a molybdenum-niobium alloy can be used. For the conductive oxide forming the second top layer 66, for example, ITO or IZO can be used. It should be noted that the upper portion 62 may comprise three or more layers or may consist of a single layer. The upper portion 62 may further include a layer formed of an insulating material.

Common voltage is applied to the partition 6A. This common voltage is applied to each of the upper electrodes UE1, UE2 and UE3 which are in contact with the lower portions 61. Pixel voltage is applied to the lower electrodes LE1, LE2 and LE3 through the pixel circuits 1 provided in subpixels SP1, SP2 and SP3, respectively, based on the video signals of the signal lines SL.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

When the display device DSP is manufactured, a large-scaled mother substrate in which a plurality of areas (panel portions) each corresponding to the display device DSP are formed is prepared. A configuration which could be applied to this mother substrate is explained below.

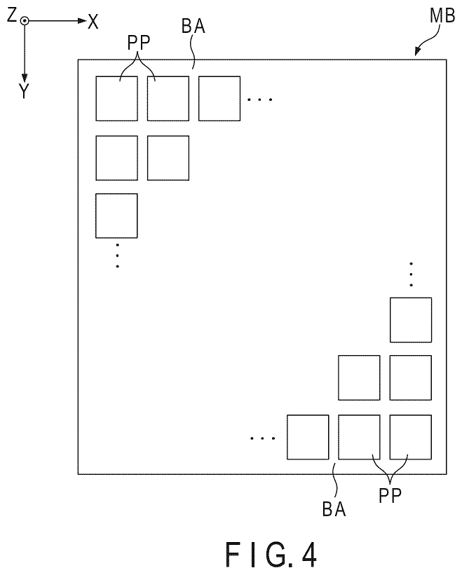

FIG. 4 is a schematic plan view of a mother substrate MB (a mother substrate for a display device) according to the embodiment. The mother substrate MB is, for example, rectangular as shown in the figure. However, the mother substrate MB may have another shape such as a circle.

The mother substrate MB comprises a plurality of panel portions PP provided in matrix, and a margin area BA around these panel portions PP. In the example of FIG. 4, the panel portions PP are arranged via the margin area BA in the X-direction and the Y-direction. It should be noted that the layout form of the panel portions PP in the mother substrate MB is not limited to this example. As another example, several panel portions PP may be arranged without intervention of the margin area BA.

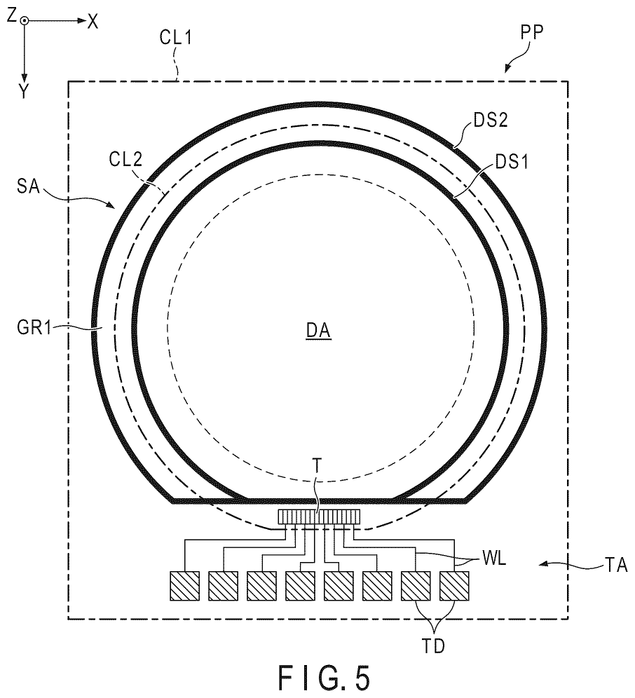

FIG. 5 is a schematic plan view of the panel portion PP. The outer shape of the panel portion PP corresponds to a cut line CL1 for cutting the panel portion PP out of the mother substrate MB.

The panel portion PP has the display area DA and surrounding area SA described above. The surrounding area SA in the panel portion PP corresponds to the area located between the display area DA and the cut line CL1.

The surrounding area SA further has a cut line CL2 which is supposed to be the outer shape of the substrate 10 of the display device DSP. The surrounding area SA includes an inspection area TA between the cut lines CL1 and CL2. In the inspection area TA, a plurality of inspection pads TD for inspecting the operation of the display panel PNL are provided. Each inspection pad TD is connected to the terminal portion T via a line WL.

The cut line CL2 passes through the area located between the terminal portion T and each inspection pad TD near the terminal portion T. In other words, the cut line CL2 intersects each line WL.

When the display device DSP is manufactured, the panel portion PP is cut out from the mother substrate MB along the cut line CL1. Further, an inspection is performed for the cut out panel portion PP, using the inspection pads TD. After this inspection, the inspection area TA is separated from the panel portion PP along the cut line CL2.

The panel portion PP comprises dam structures DS1 and DS2. The dam structure DS1 is located between the cut line CL2 and the display area DA and surrounds the display area DA. The dam structure DS2 is located in the inspection area TA and surrounds the cut line CL2. In the example of FIG. 5, the dam structures DS1 and DS2 join together near the terminal portion T, and this joined portion passes through the area located between the terminal portion T and the display area DA.

A large part of the cut line CL2 is located between the dam structures DS1 and DS2. It should be noted that, in the example of FIG. 5, the cut line CL2 is located outside the dam structures DS1 and DS2 near the terminal portion T. In other words, the cut line CL2 intersects the dam structure DS2 near the terminal portion T.

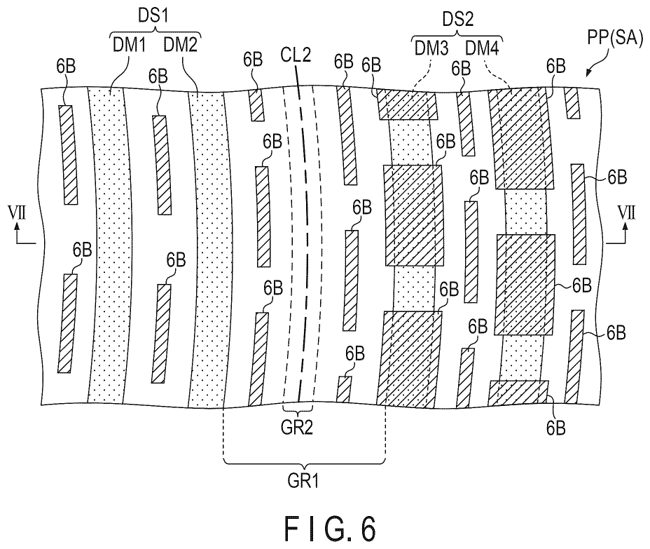

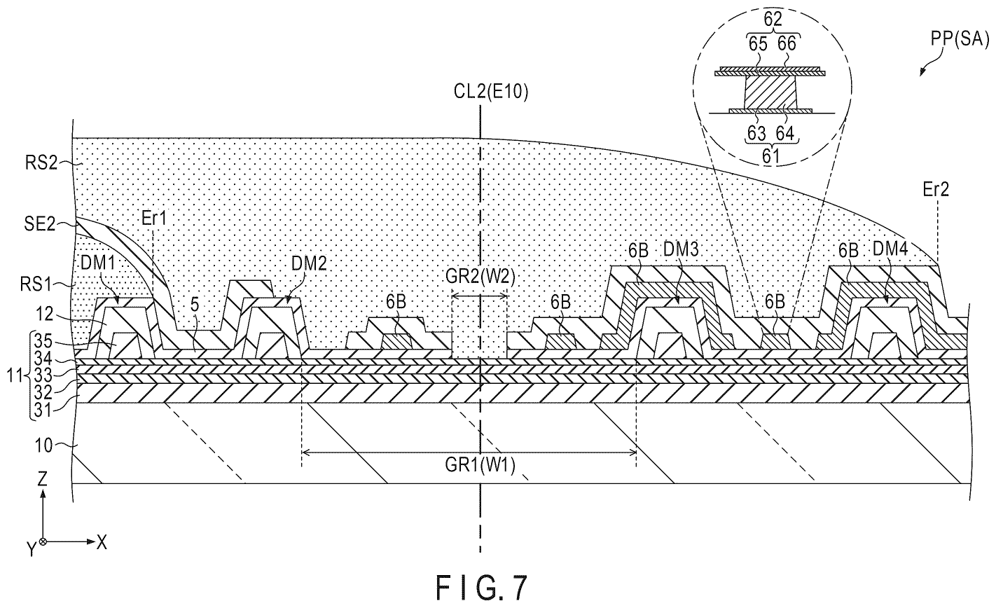

FIG. 6 is a schematic plan view in which the vicinity of the cut line CL2 is enlarged. FIG. 7 is the schematic cross-sectional view of the panel portion PP along the VII-VII line of FIG. 6.

As shown in FIG. 6, the dam structure DS1 comprises two dam portions DM1 and DM2. The dam structure DS2 comprises two dam portions DM3 and DM4. The number of dam portions provided in each of the dam structures DS1 and DS2 is not limited to two, and may be one or may be three or greater.

A large number of partitions (second partitions) 6B are provided in the surrounding area SA. For example, these partitions 6B are spaced apart from each other and extend lengthwise along the dam portions DM1, DM2, DM3 and DM4 and the cut line CL2.

As shown in the enlarged view of FIG. 7, in a manner similar to that of the partition 6A, each partition 6B comprises a lower portion (second lower portion) 61 including a bottom layer 63 and a stem layer 64, and an upper portion (second upper portion) 62 including a first top layer 65 and a second top layer 66. In the partition 6B, similarly, the both end portions of the upper portion 62 protrude from the side surfaces of the lower portion 61 (the side surfaces of the stem layer 64).

As shown in FIG. 7, the circuit layer 11 described above comprises inorganic insulating layers 31, 32, 33 and 34 and an organic insulating layer 35 provided in order on the substrate 10. Although not shown in FIG. 7, the circuit layer 11 further comprises metal layers and semiconductor layers provided between these insulating layers. Each of the inorganic insulating layers 31, 32, 33 and 34 is formed of an inorganic insulating material such as silicon nitride, silicon oxide or silicon oxynitride. For example, the inorganic insulating layer 33 is formed of silicon oxide, and the inorganic insulating layer 34 is formed of silicon nitride. The organic insulating layer 35 is formed of an organic insulating material such as polyimide.

For example, each of the dam portions DM1, DM2, DM3 and DM4 consists of the organic insulating layer 35, and the organic insulating layer 12 which covers the organic insulating layer 35. All of the dam portions DM1, DM2, DM3 and DM4 are provided on the inorganic insulating layer 34 and covered with the rib layer 5. All of the partitions 6B are provided on the rib layer 5.

The dam portions DM1 and DM2 function to dam up the resin layer RS1 before it is cured. The dam portions DM3 and DM4 function to dam up the resin layer RS2 before it is cured. In the example of FIG. 7, the end portion Er1 of the resin layer RS1 is located above the dam portion DM1. The end portion Er2 of the resin layer RS2 is located above the dam portion DM4. However, the position of the end portion Er1 or Er2 is not limited to this example.

The sealing layer SE2 covers the end portion Er1 of the resin layer RS1. Further, the sealing layer SE2 covers the rib layer 5 and the partitions 6B in the area located between the end portion Er1 and the cut line CL2 and the area located on the outside of the cut line CL2 (the right side of the figure).

The cut line CL2 overlaps the substrate 10, the inorganic insulating layers 31, 32, 33 and 34 and the resin layer RS2. After the panel portion PP is cut along the cut line CL2, of the substrate 10, the portion which overlaps the cut line CL2 becomes the outer edge E10 of the substrate 10. In other words, after the panel portion PP is cut along the cut line CL2, in the display device DSP, the sealing layer SE2 covers the rib layer 5 in the area located between the end portion Er1 of the resin layer RS1 and the outer edge E10 of the substrate 10.

The organic insulating layer 12 is not provided between the dam portions DM2 and DM3. From another viewpoint, the organic insulating layer 12 has a first groove GR1 between the dam portions DM2 and DM3. The first groove GR1 surrounds the display area DA as shown in FIG. 5. A large part of the cut line CL2 is located in the first groove GR1.

The rib layer 5 has a second groove GR2 which overlaps the cut line CL2. In the example of FIG. 6 and FIG. 7, the second groove GR2 overlaps part of the first groove GR1. In other words, the first groove GR1 has a portion which overlaps the second groove GR2 and a portion which does not overlap the second groove GR2.

As shown in FIG. 7, the first groove GR1 has width W1. The second groove GR2 has width W2 which is less than width W1 (W1>W2). For example, width W2 is greater than or equal to 100 μm. However, the specific width is not limited to this example.

In the example of FIG. 7, the sealing layer SE2 is removed in the second groove GR2. By this configuration, the inorganic insulating layer 34 is exposed from the rib layer 5 and the sealing layer SE2 through the second groove GR2. The second groove GR2 is covered with the resin layer RS2.

In the example of FIG. 7, in addition, the sealing layer SE2 is removed near the dam portion DM2. The area in which the sealing layer SE2 is removed in this manner may surround the display area DA together with the dam portion DM2.

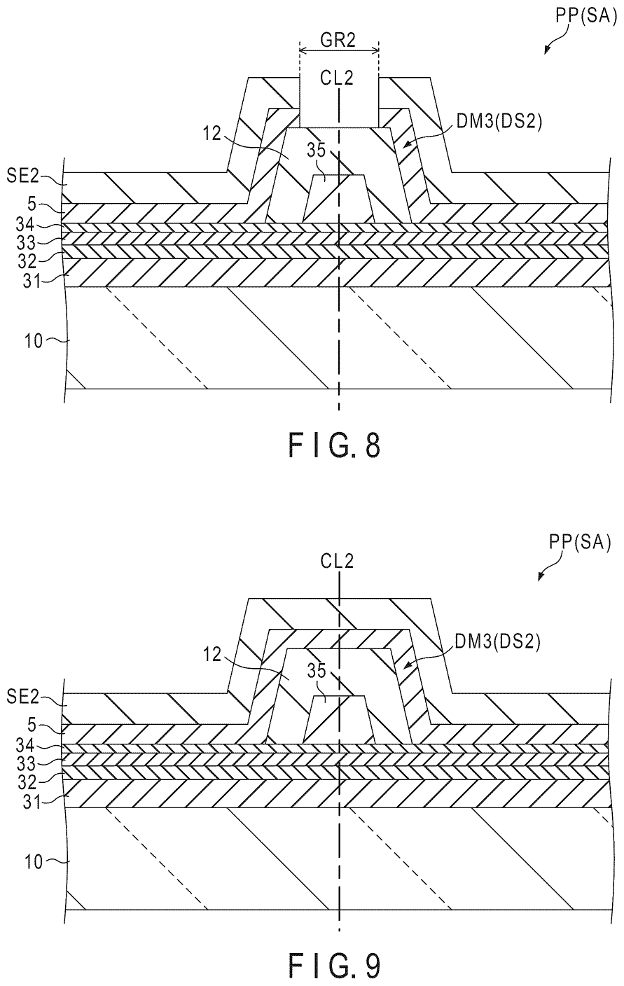

FIG. 8 is a schematic cross-sectional view showing an example of the structure of a portion in which the dam structure DS2 and the cut line CL2 intersect each other. FIG. 9 is a schematic cross-sectional view showing another example of the structure of a portion in which the dam structure DS2 and the cut line CL2 intersect each other. These figures focus attention on the dam portion DM3. However, a similar structure can be applied to the dam portion DM4. It should be noted that the resin layer RS2 is omitted in these figures.

In the example of FIG. 8, the second groove GR2 is formed in the rib layer 5 on the dam portion DM3 as well. Further, the sealing layer SE2 is removed in the second groove GR2. By this configuration, the upper surface of the dam portion DM3 is exposed from the rib layer 5 and the sealing layer SE2.

To the contrary, in the example of FIG. 9, the second groove GR2 is not formed on the dam portion DM3. In other words, the dam portion DM3 is covered with the rib layer 5 and the sealing layer SE2 in the portion intersecting with the cut line CL2.

In all of the examples of FIG. 6 to FIG. 9, the partitions 6B are not provided at positions which overlap the cut line CL2. This configuration can prevent the partitions 6B from blocking the cutting performed along the cut line CL2.

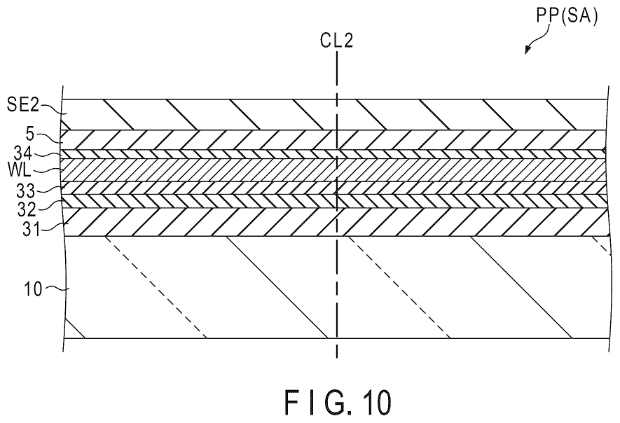

FIG. 10 is a schematic cross-sectional view showing an example of the structure of a portion in which the line WL and cut line CL2 shown in FIG. 5 intersect each other. In the example of this figure, the line WL is provided between the inorganic insulating layers 33 and 34. It should be noted that the position of the line WL is not limited to this example.

The line WL is formed of a metal material. If a moisture path to this line WL is formed, the line WL may be corroded. In the example of FIG. 10, the second groove GR2 is not formed in the rib layer 5 in the portion in which the line WL intersects with the cut line CL2. The line WL is entirely covered with the inorganic insulating layer 34, the rib layer 5 and the sealing layer SE2. This configuration can prevent the formation of the above moisture path to the line WL.

It should be noted that the first and second grooves GR1 and GR2 exemplarily shown in FIG. 7 may be provided for the cut line CL1 as well as the cut line CL2. Further, the sealing layer SE2 may be removed in the second groove GR2 provided for the cut line CL1.

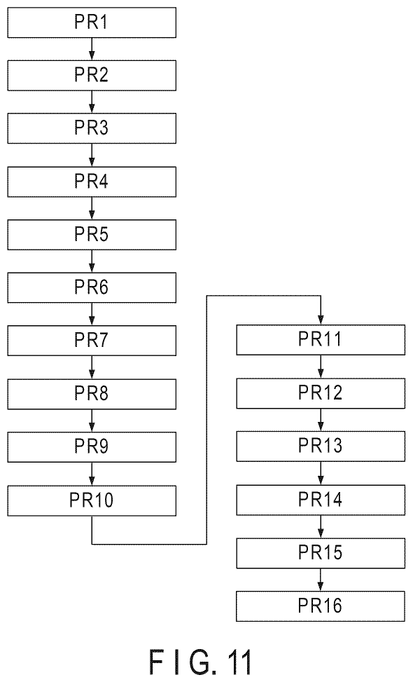

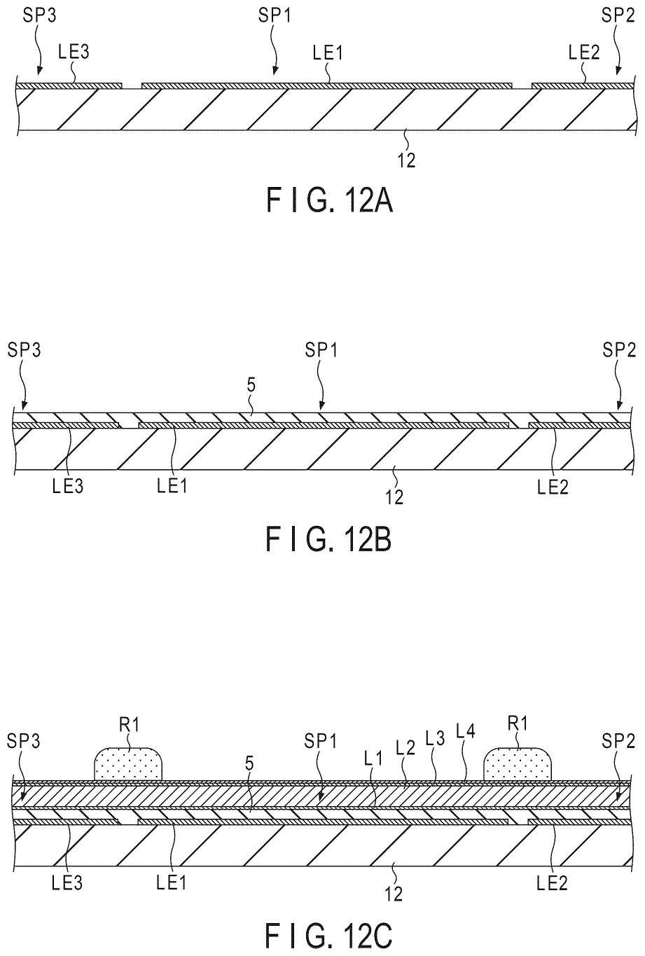

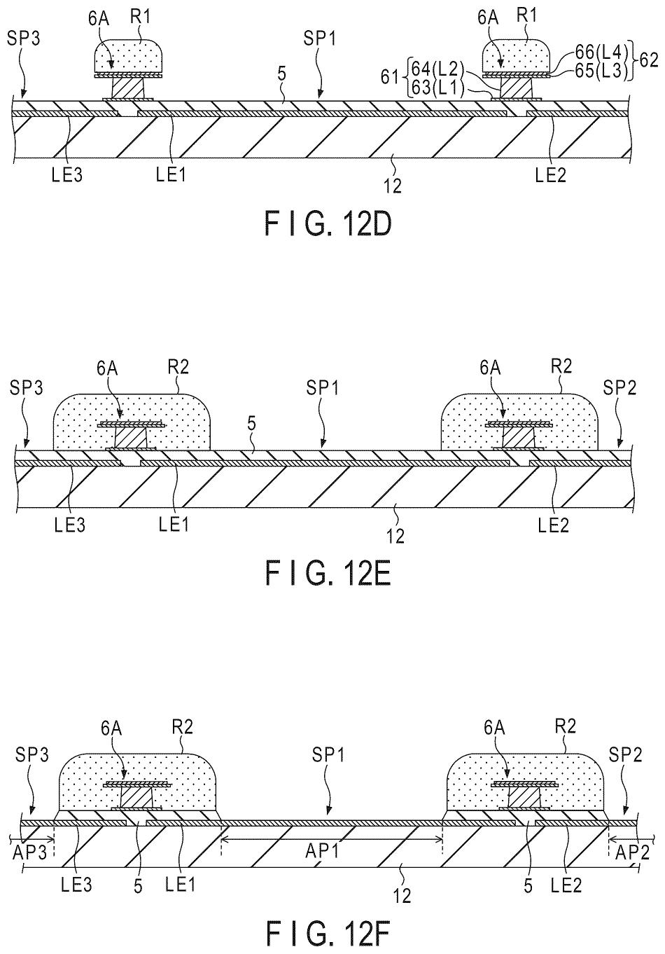

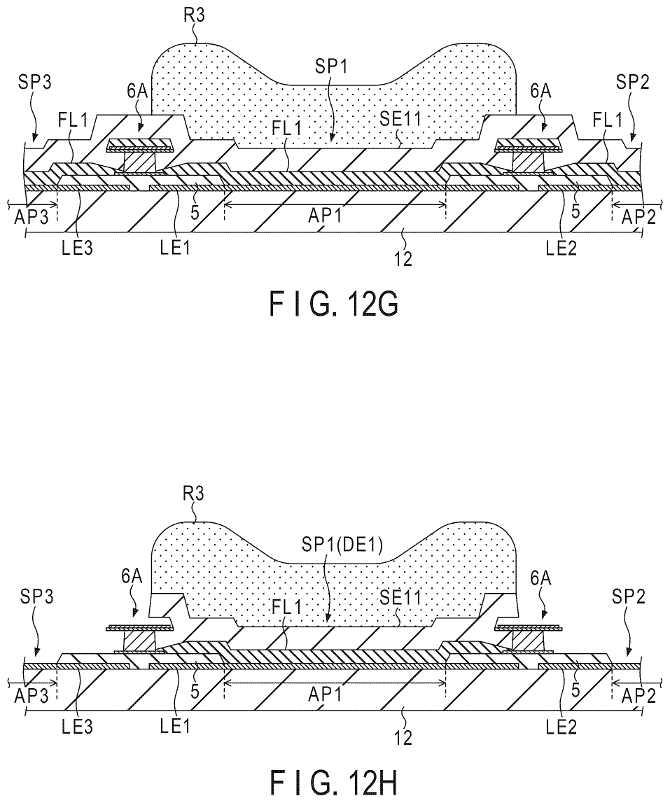

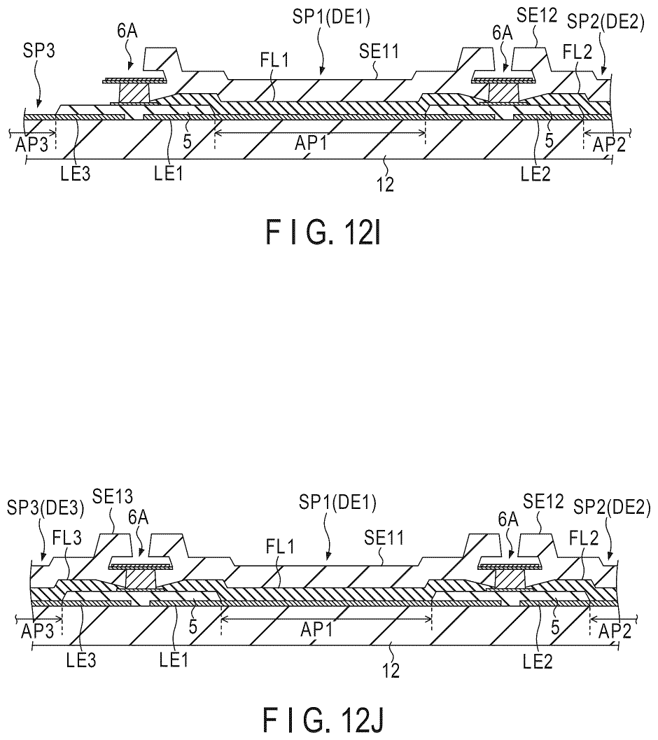

Now, this specification explains an example of the manufacturing method of the display device DSP. FIG. 11 is a flowchart showing an example of the manufacturing method of the display device DSP. Each of FIG. 12A to FIG. 12J is a schematic cross-sectional view showing the manufacturing process of the display device DSP. In FIG. 12A to FIG. 12J, the display area DA is mainly looked at, and the elements located under the organic insulating layer 12 are omitted.

To form the panel portions PP, first, the circuit layer 11 which includes the inorganic insulating layers 31, 32, 33 and 34, the organic insulating layer 35 and a plurality of metal layers and semiconductor layers described above is formed above the substrate 10 of the mother substrate MB (process PR1 in FIG. 11). Further, the organic insulating layer 12 having the first groove GR1 described above is formed (process PR2 in FIG. 11).

After process PR2, as shown in FIG. 12A, the lower electrodes LE1, LE2 and LE3 are formed on the organic insulating layer 12 (process PR3 in FIG. 11).

Subsequently, as shown in FIG. 12B, the rib layer 5 which covers the lower electrodes LE1, LE2 and LE3 is formed in the entire mother substrate MB (process PR4 in FIG. 11). At this time, the pixel aperture AP1, AP2 or AP3 is not provided in the rib layer 5. The rib layer 5 may be formed by chemical vapor deposition (CVD).

After the formation of the rib layer 5, a process for forming the partitions 6A and 6B is performed (process PR5 in FIG. 11). In process PR5, as shown in FIG. 12C, a first layer L1 which is processed so as to be the bottom layer 63, a second layer L2 which is processed so as to be the stem layer 64, a third layer L3 which is processed so as to be the first top layer 65 and a fourth layer L4 which is processed so as to be the second top layer 66 are formed in order in the entire mother substrate MB. Further, a resist R1 is provided on the fourth layer L4. The resist R1 has been patterned into the shape of the partitions 6A and 6B. The first layer L1, the second layer L2, the third layer L3 and the fourth layer L4 are formed by, for example, sputtering.

Subsequently, the first layer L1, the second layer L2, the third layer L3 and the fourth layer L4 are patterned using the resist R1 as a mask. For example, the first layer L1 is formed of titanium nitride. The second layer L2 is formed of aluminum. The third layer L3 is formed of titanium. The fourth layer L4 is formed of ITO. In this case, the above patterning may include wet etching for removing the portion of the fourth layer L4 exposed from the resist R1, dry etching for removing the portions of the first, second and third layers L1, L2 and L3 exposed from the resist R1, and wet etching for reducing the width of the second layer L2.

Through process PR5, as shown in FIG. 12D, the partition 6A is formed in the display area DA. Further, the partitions 6B are formed in the surrounding area SA. After the formation of the partitions 6A and 6B, the resist R1 is removed (peeled off).

Subsequently, a process for providing the pixel apertures AP1, AP2 and AP3 is performed (process PR6 in FIG. 11). In this process PR6, as shown in FIG. 12E, a resist R2 which covers the partition 6A is formed. Further, dry etching for the rib layer 5 is performed using the resist R2 as a mask. By this process, as shown in FIG. 12F, the pixel apertures AP1, AP2 and AP3 in which the lower electrodes LE1, LE2 and LE3 are exposed are formed in the rib layer 5. After the dry etching described above, the resist R2 is removed (peeled off). It should be noted that the pixel apertures AP1, AP2 and AP3 may be formed before the formation of the partitions 6A and 6B.

After process PR6, a process for removing the rib layer 5 in the inspection pads TD shown in FIG. 5 is performed (process PR7 in FIG. 11). In process PR7, a resist which is open in the inspection pads TD is provided on the rib layer 5, and dry etching is performed for the rib layer 5.

After process PR7, a process for forming the display element DE1 is performed (process PR8 in FIG. 11). To form the display element DE1, first, as shown in FIG. 12G, the stacked film FL1 and the sealing layer SE11 are formed. The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1. The organic layer OR1, the upper electrode UE1 and the cap layer CP1 may be formed by, for example, vapor deposition. The sealing layer SE11 may be formed by, for example, CVD.

The stacked film FL1 and the sealing layer SE11 are formed in the entire mother substrate MB including the surrounding area SA and the margin area BA as well as the display area DA of each panel portion PP. The stacked film FL1 is divided into a plurality of portions by the partition 6A having an overhang shape. The sealing layer SE11 continuously covers the portions into which the stacked film FL1 is divided, and the partition 6A.

Subsequently, the stacked film FL1 and the sealing layer SE11 are patterned. In this patterning, as shown in FIG. 12G, a resist R3 is provided on the sealing layer SE11. The resist R3 covers subpixel SP1 and part of the partition 6A around the subpixel.

Subsequently, an etching process using the resist R3 a mask is performed. By this process, as shown in FIG. 12H, the portions of the stacked film FL1 and the sealing layer SE11 exposed from the resist R3 are removed. In other words, of the stacked film FL1 and the sealing layer SE11, the portions which overlap the lower electrode LE1 remain, and the other portions are removed. By this process, the display element DE1 is formed in subpixel SP1. For example, in the surrounding area SA and the margin area BA, the stacked film FL1 and the sealing layer SE11 are removed by this etching process. This etching process may include wet etching and dry etching processes which are performed in order for the sealing layer SE11, the cap layer CP1, the upper electrode UE1 and the organic layer OR1. After these etching processes, the resist R3 is removed (peeled off).

After process PR8, a process for forming the display element DE2 is performed (process PR9 in FIG. 11). The display element DE2 can be formed by a procedure similar to that of the display element DE1. Specifically, when the display element DE2 is formed, the stacked film FL2 and the sealing layer SE12 are formed in the entire mother substrate MB. The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 may be formed by, for example, vapor deposition. The sealing layer SE12 may be formed by, for example, CVD. By patterning these stacked film FL2 and sealing layer SE2, the display element DE2 is formed in subpixel SP2 as shown in FIG. 12I. For example, in the surrounding area SA and the margin area BA, the stacked film FL2 and the sealing layer SE12 are removed by the etching at the time of this patterning.

After process PR9, a process for forming the display element DE3 is performed (process PR10 in FIG. 11). The display element DE3 can be formed by a procedure similar to the procedures of the display elements DE1 and DE2. Specifically, when the display element DE3 is formed, the stacked film FL3 and the sealing layer SE13 are formed in the entire mother substrate MB. The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 may be formed by, for example, vapor deposition. The sealing layer SE13 may be formed by, for example, CVD. By patterning these stacked film FL3 and sealing layer SE13, the display element DE3 is formed in subpixel SP3 as shown in FIG. 12J. For example, in the surrounding area SA and the margin area BA, the stacked film FL3 and the sealing layer SE13 are removed by the etching at the time of this patterning.

Here, it is assumed that the display elements DE1, DE2 and DE3 are formed in this order. However, the display elements DE1, DE2 and DE3 may be formed in another order.

The stacked films FL1, FL2 and FL3 formed by vapor deposition in processes PR8 to PR10 may have poor adherence to the base. Therefore, the stacked films FL1, FL2 and FL3 and the sealing layers SE11, SE12 and SE13 which cover these stacked films may be removed from the base when the display device DSP is manufactured.

This removal easily occurs in a case where the stacked films FL1, FL2 and FL3 are continuously formed in a wide range. In the display area DA, the stacked films FL1, FL2 and FL3 are divided into pieces by the partition 6A. Thus, the removal described above is prevented.

Further, in this embodiment, the partitions 6B are provided in the surrounding area SA. By this configuration, the stacked films FL1, FL2 and FL3 are divided by the partitions 6B in the surrounding area SA as well, and the removal described above is prevented.

After process PR10, the resin layer RS1 is formed (process PR11 in FIG. 11). The resin layer RS1 may be formed inside the dam structure DS1 by, for example, an ink-jet method. After process PR11, the sealing layer SE2 is formed in the entire mother substrate MB by, for example, CVD (process PR12 in FIG. 11).

After process PR12, etching for removing the rib layer 5 and sealing layer SE2 covering the terminal portion T is performed (process PR13 in FIG. 11). The etching is, for example, dry etching. The second groove GR2 described above is formed by this etching. In this embodiment, the sealing layer SE2 is removed together with the rib layer 5 by the etching at the position where the second groove GR2 should be formed.

After process PR13, the resin layer RS2 is formed (process PR14 in FIG. 11). The resin layer RS2 may be formed inside the dam structure DS2 by, for example, an ink-jet method. The dam structure DS2 functions to dam up the resin layer RS2 before it is cured.

The resin layer RS2 may be formed by a photolithographic process. In this case, first, a photosensitive resin which is processed so as to be the resin layer RS2 is formed in the entire mother substrate MB. Subsequently, the processes of pre-bake, exposure, development and burning are performed for the photosensitive resin. Through these processes, the resin layer RS2 is formed in each panel portion PP.

After process PR14, the mother substrate MB is cut along the cut line CL1 (process PR15 in FIG. 11). Subsequently, the inspection area TA is cut along the cut line CL2 after an inspection process using the inspection pads TD (process TR16 in FIG. 11). By this process, the display device DSP is completed. For the cutting in processes PR14 and PR15, for example, laser cutting for applying infrared laser beams along the cut lines CL1 and CL2 can be used. It should be noted that the cutting in processes PR14 and PR15 may be performed by another method such as scribe cutting.

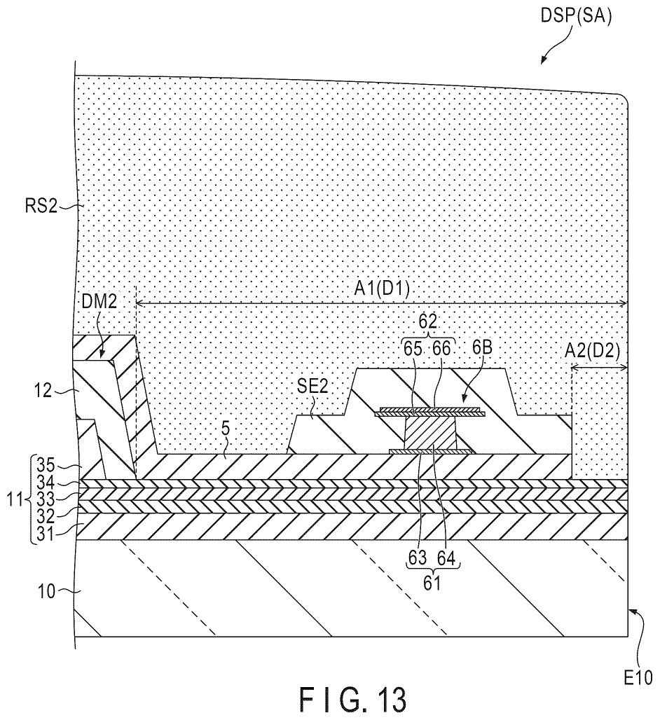

FIG. 13 is a schematic cross-sectional view showing the vicinity of the outer edge E10 of the substrate 10 in the display device DSP manufactured by the manufacturing method described above. In the display device DSP, a first area A1 in which the organic insulating layer 12 is not provided and a second area A2 in which the rib layer 5 is not provided are formed along the outer edge E10.

The first area A1 corresponds to, of the first groove GR1, the portion located on the display area DA side relative to the cut line CL2. The second area A2 corresponds to, of the second groove GR2, the portion located on the display area DA side relative to the cut line CL2.

The second area A2 is covered with the resin layer RS2. The second area A2 overlaps part of the first area A1. In other words, the first area A1 has a portion which overlaps the second area A2 and a portion which does not overlap the second area A2.

The first area A1 is formed in the range of a first distance D1 from the outer edge E10. The second area A2 is formed in the range of a second distance D2 from the outer edge E10. As is clear from the relationship of widths W1 and W2 shown in FIG. 7, the second distance D2 is less than the first distance D1 (D1>D2).

In this embodiment, the sealing layer SE2 is removed in the second area A2. By this configuration, the inorganic insulating layer 34 is exposed from the rib layer 5 and the sealing layer SE2 in the second area A2.

For example, the display device DSP could have the first area A1 and the second area A2 over the whole surrounding area of the display area DA. It should be noted that at least one of the first area A1 and the second area A2 may not be formed near the terminal portion T shown in FIG. 5.

The embodiment can improve the yield of the display device DSP as explained below.

In a configuration in which the panel portion PP does not have the second area A2 during the manufacturing process of the display device DSP, there is a possibility that the rib layer 5 and sealing layer SE2 formed of inorganic insulating materials are partly damaged near the cut line CL2 when the panel portion PP is cut along the cut line CL2. In this case, a crack may be generated in the rib layer 5 and the sealing layer SE2 based on the damaged portions of the rib layer 5 and the sealing layer SE2.

To the contrary, when the second groove GR2 is provided along the cut line CL2 like the embodiment, the rib layer 5 is not easily damaged at the time of cutting. Therefore, the crack described above can be prevented.

Further, in the embodiment, the sealing layer SE2 is removed in the second groove GR2. By this configuration, similarly, the sealing layer SE2 is not easily damaged, and thus, the crack described above can be further satisfactorily prevented.

In the configuration shown in FIG. 7, the resin layer RS2 overlaps the cut line CL2. Thus, the thick resin layer RS2 has to be cut together with the substrate 10 etc., at the time of cutting along the cut line CL2. If the laser cutting described above is applied, the portion including the resin layer RS2 can be satisfactorily cut compared with a mechanical method such as scribe cutting.

However, when laser cutting is used, the damage to the rib layer 5 and the sealing layer SE2 described above is easily caused. Thus, the configuration in which the second groove GR2 is provided like the embodiment exerts a good effect when laser cutting is used.

As another form of the first groove GR1 and the second groove GR2, they could be formed so as to have substantially the same width. However, in this case, as the rib layer 5 which is the base of the partitions 6B is not present in the first groove GR1, the partitions 6B cannot be provided in the first groove GR1.

As described above, the partitions 6B function to prevent the removal of the stacked films FL1, FL2 and FL3 formed in the surrounding area SA during the manufacturing process of the display device DSP, and the sealing layers SE11, SE12 and SE13 which cover these stacked films FL1, FL2 and FL3. For this reason, in a case where the partitions 6B cannot be provided in the first groove GR1, the possibility that the removal described above is caused in the first groove GR1 is increased.

Therefore, like the embodiment, the second groove GR2 should be preferably provided so as to overlap part of the first groove GR1. By this configuration, the partitions 6B can be provided for the area in which the rib layer 5 is present in the first groove GR1.

Various desirable effects can be obtained from the present embodiment in addition to the effects described here.

The second to fourth embodiments are disclosed below. In these embodiments, the configurations of the second groove GR2 and the second area A2 are different from the first embodiment. Regarding the display device DSP, the mother substrate MB, the panel portion PP and the manufacturing method, configurations similar to those of the first embodiment can be applied to configurations which are not particularly referred to.

### Second Embodiment

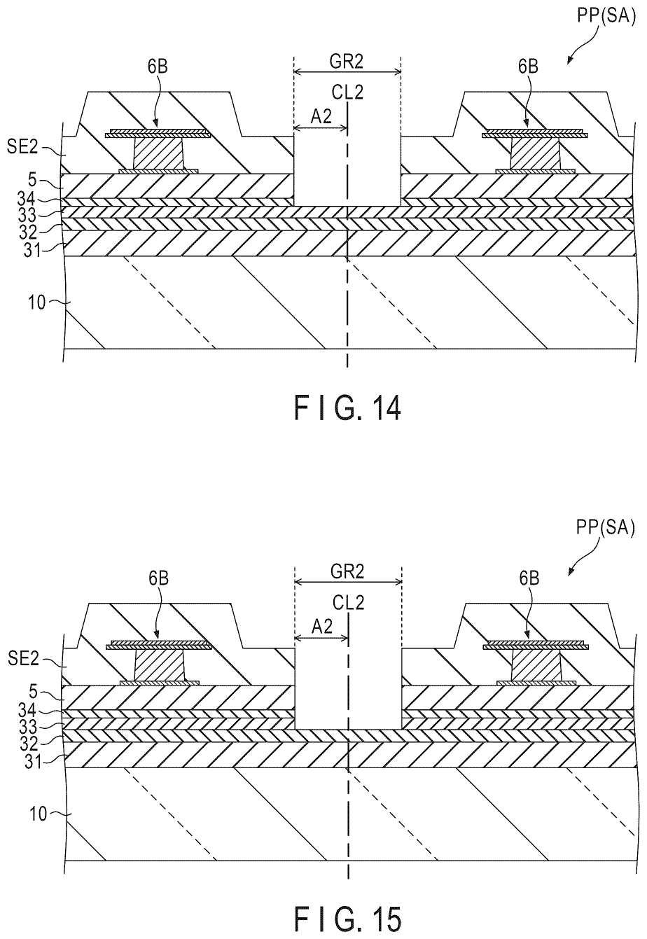

FIG. 14 is a schematic cross-sectional view of the vicinity of a cut line CL2 in a panel portion PP according to the second embodiment. In this figure, a resin layer RS2 is omitted.

In the example of FIG. 14, in addition to a sealing layer SE2, an inorganic insulating layer (first underlayer) 34 is removed in a second groove GR2. When this panel portion PP is cut along the cut line CL2, a display device DSP in which a rib layer 5, the sealing layer SE2 and the inorganic insulating layer 34 are removed in a second area A2 can be obtained.

To obtain the configuration of FIG. 14, for example, the inorganic insulating layer 34 is removed by etching at the position where the second groove GR2 should be formed after the inorganic insulating layer 34 is formed in process PR1 of FIG. 11. Further, in a manner similar to that of the first embodiment, the second groove GR2 is formed by removing the rib layer 5 and the sealing layer SE2 by etching in process PR13. As another example, the inorganic insulating layer 34 which overlaps the second groove GR2 may be removed when the second groove GR2 is formed by the etching of process PR13.

If the inorganic insulating layer 34 is removed in the second groove GR2 like this embodiment, the damage to the inorganic insulating layer 34 can be also prevented when the panel portion PP is cut along the cut line CL2. This configuration can prevent a crack to be caused based on the damaged portion of the inorganic insulating layer 34 and can further improve the yield of the display device DSP.

### Third Embodiment

FIG. 15 is a schematic cross-sectional view of the vicinity of a cut line CL2 in a panel portion PP according to the third embodiment. In this figure, a resin layer RS2 is omitted.

In the example of FIG. 15, in addition to a sealing layer SE2 and an inorganic insulating layer 34, an inorganic insulating layer (second underlayer) 33 is removed in a second groove GR2. When this panel portion PP is cut along the cut line CL2, a display device DSP in which a rib layer 5, the sealing layer SE2 and the inorganic insulating layers 33 and 34 are removed in a second area A2 can be obtained.

To obtain the configuration of FIG. 15, for example, the inorganic insulating layers 33 and 34 are removed by etching at the position where the second groove GR2 should be formed after the inorganic insulating layers 33 and 34 are formed in process PR1 of FIG. 11. Further, in a manner similar to that of the first embodiment, the second groove GR2 is formed by removing the rib layer 5 and the sealing layer SE2 by etching in process PR13. As another example, the inorganic insulating layers 33 and 34 which overlap the second groove GR2 may be removed when the second groove GR2 is formed by the etching of process PR13.

If the inorganic insulating layer 33 and 34 are removed in the second groove GR2 like this embodiment, the damage to the inorganic insulating layers 33 and 34 can be also prevented when the panel portion PP is cut along the cut line CL2. This configuration can prevent a crack to be caused based on the damaged portions of the inorganic insulating layers 33 and 34 and can further improve the yield of the display device DSP.

### Fourth Embodiment

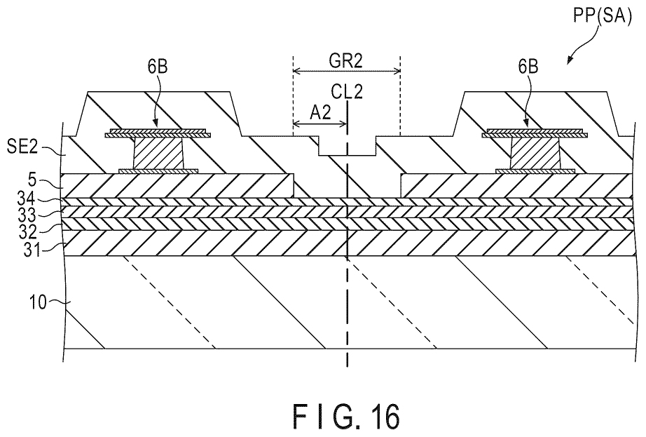

FIG. 16 is a schematic cross-sectional view of the vicinity of a cut line CL2 in a panel portion PP according to the fourth embodiment. In this figure, a resin layer RS2 is omitted.

In the example of FIG. 16, none of a sealing layer SE2, an inorganic insulating layer 33 and an inorganic insulating layer 34 is removed in a second groove GR2. When this panel portion PP is cut along the cut line CL2, a display device DSP in which the second area A2 is covered with the sealing layer SE2 can be obtained.

To obtain the configuration of FIG. 16, the second groove GR2 needs to be formed in the rib layer 5 before the formation of the sealing layer SE2. For example, the second groove GR2 can be formed by the etching of the rib layer 5 in process PR7 of FIG. 11.

Even if the sealing layer SE2 is not removed in the second groove GR2 like this embodiment, similarly, the damage to the rib layer 5 can be prevented when the panel portion PP is cut along the cut line CL2. Thus, the yield of the display device DSP can be improved in a manner similar to that of the first embodiment.

In addition to the configurations disclosed in the first to fourth embodiments described above, various configurations can be applied to the second groove GR2 and the second area A2. For example, in the configurations of the second and third embodiments, the second groove GR2 (the second area A2) may be covered with the sealing layer SE2 in a manner similar to that of the fourth embodiment.

In the configurations of the first to fourth embodiments, at least one of the inorganic insulating layers 31 and 32 may be removed in the second groove GR2 (the second area A2). It should be noted that, if all of the inorganic insulating layers 31, 32, 33 and 34 are removed, the substrate 10 is exposed in the second groove GR2 during the manufacturing process of the display device DSP. In this case, undesired substances may be extracted from the substrate 10 depending on the material of the substrate 10. From this perspective, the substrate 10 should be preferably covered with at least one of the inorganic insulating layers 31, 32, 33 and 34 in the second groove GR2.

All of the display devices and manufacturing methods that can be implemented by a person of ordinary skill in the art through arbitrary design changes to the display device and manufacturing method disclosed above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate;
an organic insulating layer provided above the substrate over a display area which displays an image and a surrounding area located around the display area;
a lower electrode provided above the organic insulating layer in the display area;
a rib layer provided above the organic insulating layer and the lower electrode and having a pixel aperture which overlaps the lower electrode;
an organic layer which covers the lower electrode through the pixel aperture and emits light based on application of voltage;
an upper electrode which covers the organic layer; and
a first partition which includes a first lower portion provided above the rib layer and a first upper portion having an end portion protruding from a side surface of the first lower portion, and surrounds the pixel aperture, wherein
the surrounding area has:
a first area which is formed along an outer edge of the substrate and in which the organic insulating layer is not provided; and
a second area which is formed along the outer edge and overlaps part of the first area and in which the rib layer is not provided.

2. The display device of claim 1, wherein
the first area is formed in a range of a first distance from the outer edge, and
the second area is formed in a range of a second distance which is less than the first distance from the outer edge.

3. The display device of claim 1, further comprising:
a first resin layer which covers the display area; and
a sealing layer which is formed of an inorganic insulating material and covers the first resin layer, wherein
an end portion of the first resin layer is located in the surrounding area, and
the sealing layer covers the rib layer in an area located between the end portion of the first resin layer and the outer edge of the substrate.

4. The display device of claim 3, further comprising
a plurality of second partitions each of which includes:
a second lower portion provided above the rib layer in the surrounding area; and
a second upper portion which has an end portion protruding from a side surface of the second lower portion, wherein
the sealing layer covers the second partitions.

5. The display device of claim 3, wherein
the sealing layer is removed in the second area.

6. The display device of claim 3, wherein
the sealing layer covers the second area.

7. The display device of claim 3, further comprising a second resin layer which covers the sealing layer in the display area and the surrounding area.

8. The display device of claim 7, wherein
the second resin layer covers the second area.

9. The display device of claim 1, further comprising a first underlayer which is formed of an inorganic insulating material and is provided under the rib layer, wherein
the first underlayer is removed in the second area.

10. The display device of claim 9, further comprising a second underlayer which is formed of an inorganic insulating material and is provided under the first underlayer, wherein
the second underlayer is removed in the second area.

11. A manufacturing method of a display device, the method including:
forming an organic insulating layer which has a first groove surrounding a display area above a substrate;
forming a lower electrode above the organic insulating layer in the display area;
forming a rib layer above the organic insulating layer and the lower electrode;
forming, in the display area, a first partition which includes a first lower portion provided above the rib layer and a first upper portion having an end portion protruding from a side surface of the first lower portion;
forming a pixel aperture which overlaps the lower electrode in the rib layer;
forming an organic layer which covers the lower electrode through the pixel aperture and emits light based on application of voltage;
forming an upper electrode which covers the organic layer;
forming a second groove which overlaps part of the first groove in the rib layer by etching for the rib layer; and
cutting the substrate along a cut line which overlaps the first groove and the second groove.

12. The manufacturing method of claim 11, wherein
the first groove has a first width, and
the second groove has a second width which is less than the first width.

13. The manufacturing method of claim 11, further including:
after the upper electrode is formed, and before the substrate is cut,
forming a first resin layer which covers the display area; and
forming a sealing layer which is formed of an inorganic insulating material and covers the first resin layer, wherein
an end portion of the first resin layer is located between the display area and the cut line, and
the sealing layer covers the rib layer in an area located between the end portion of the first resin layer and the cut line.

14. The manufacturing method of claim 13, further including:
before the sealing layer is formed, forming, in a surrounding area located around the display area, a plurality of second partitions each of which includes a second lower portion provided above the rib layer and a second upper portion having an end portion protruding from a side surface of the second lower portion, wherein
the sealing layer is formed so as to cover the second partitions.

15. The manufacturing method of claim 13, wherein
etching for forming the second groove is performed after forming the sealing layer, and
by the etching, the sealing layer is removed together with the rib layer at a position where the second groove should be formed.

16. The manufacturing method of claim 13, further including
forming a second resin layer which covers the sealing layer in the display area and a surrounding area located around the display area.

17. The manufacturing method of claim 16, wherein
the second resin layer covers the second groove, and
the second resin layer is cut together with the substrate when the substrate is cut.

18. The manufacturing method of claim 11, further including:
before the organic insulating layer is formed, forming a first underlayer formed of an inorganic insulating material above the substrate; and
removing the first underlayer at a position where the second groove should be formed.

19. The manufacturing method of claim 18, further including:
before the first underlayer is formed, forming a second underlayer formed of an inorganic insulating material above the substrate; and
removing the second underlayer at a position where the second groove should be formed.

20. The manufacturing method of claim 11, wherein
the substrate is cut by a laser.
